(19) United States
(12) Patent Application Publication
(10) Pub. No.: US 2011/0256723 A1
(43) Pub. Date: Oct. 20, 2011

(54) METHOD FOR FORMING SEMICONDUCTOR DEVICE

(75) Inventors: Ki Lyoung LEE, Hwaseong (KR); Cheol Kyu Bok, Icheon (KR); Jung Hyung Lee, Seoul (KR)

(73) Assignee: Hynix Semiconductor Inc., Icheon-si (KR)

(21) Appl. No.: 12/981,414

(22) Filed: Dec. 29, 2010

(30) Foreign Application Priority Data
Apr. 15, 2010 (KR) 10-2010-0034748

(51) Int. Cl. H01L 21/302

(52) U.S. Cl. 438/694; 257/E21.214

(57) ABSTRACT

A method for forming a semiconductor device is disclosed. A method for forming a semiconductor device includes forming a first sacrificial hard mask layer over a semiconductor substrate including an etch layer, forming a first spacer over the first sacrificial hard mask layer, forming a first sacrificial hard mask pattern by etching the first sacrificial hard mask layer using the first spacer as an etch mask, forming a second spacer at both sidewalls of the first sacrificial hard mask pattern, partially isolating the second spacer, and forming a pad pattern over the second spacer. As a result, a line-and-space pattern such as a control gate of the NAND flash memory and a pad portion coupled to a drain contact in an X-decoder of a peripheral circuit region can be easily implemented.

### CROSS-REFERENCE TO RELATED APPLICATION

The priority of Korean patent application No. 10-2010-0034748 filed on 15 Apr. 2010, the disclosure of which is hereby incorporated in its entirety by reference, is claimed.

### BACKGROUND OF THE INVENTION

Embodiments of the present invention relate to a method for forming a semiconductor device, and more particularly to a method for forming a semiconductor device using double spacer patterning technology.

Recently, most of electronic appliances comprise a semiconductor device. The semiconductor device comprises electronic elements such as a transistor, a resistor and a capacitor. These electronic elements are designed to perform a partial function of electronic elements, and are integrated on a semiconductor substrate. For example, electronic elements such as a computer or a digital camera include a memory chip for storing information and a processing chip for controlling information. The memory chip and the processing chip include electronic elements integrated on a semiconductor substrate.

The semiconductor devices have a need for an increase in an integration degree thereof, in order to satisfy consumer demands for superior performance and low prices. Such an increase in the integration degree of a semiconductor device entails a reduction in a design rule, causing patterns of a semiconductor device to be increasingly reduced. Although an entire chip area is increased in proportion to an increase in memory capacity as a semiconductor device is becoming super miniaturized and highly integrated, a unit cell area where patterns of a semiconductor device are actually formed is decreased. Accordingly, since a greater number of patterns should be formed in a limited cell area in order to achieve a desired memory capacity, there is a need for formation of microscopic (fine) patterns having a reduced critical dimension scale.

A representative method for forming such a fine pattern is a Double Patterning Technology (DPT). The DPT may be classified into a Double Expose Etch Technology (DE2T) and a Spacer Patterning Technology (SPT) that uses a spacer. The DE2T forms first patterns with a first distance subject to a given critical dimension scale and then forms a second pattern between neighboring first patterns. Thus, the distance between neighboring second patterns are within the given critical dimension scale but the distance between neighboring the first and the second patterns surpasses the given critical dimension scale.

Meanwhile, as semiconductor devices are becoming highly integrated, it is more difficult to form a line-and-space pattern of 40 nm or less using a one-time exposure process due to the limitation of ArF immersion exposure tools having a numerical aperture (NA) of 1.35. In order to solve such problems, a technology for employing a hyper numerical aperture (Hyper NA) using a high index fluid (HIF) material has recently been proposed. However, it is very difficult to apply the aforementioned technology to a semiconductor fabrication process. For an alternative proposal, a method for forming a fine pattern of 30 nm or less using an extreme ultra violet (EUV) exposure light source having a wavelength of 13.4 nm has been proposed. Up to now, the EUV has many technical limitations in exposure source, tool, photoresist film, etc., so that it is difficult to develop a device using an EUV exposure light source.

In conclusion, it is necessary to propose and develop a method for forming a fine pad pattern which can be connected to a control gate of a NAND flash memory or a drain contact of an X-decoder of a peripheral circuit region.

### BRIEF SUMMARY OF THE INVENTION

Various embodiments of the present invention are directed to providing a method for forming a semiconductor device that substantially obviates one or more problems due to limitations and disadvantages of the related art.

An object of the present invention is to provide a method for forming a semiconductor device, which can solve the problems of the related art. According to the related art, it is difficult to implement a semiconductor device due to limitations in the ArF immersion exposure device and difficulty in the EUV exposure device.

In accordance with an aspect of the present invention, a method for forming a semiconductor device includes forming a first sacrificial hard mask layer over a semiconductor substrate including an underlying layer ,the underlying layer being provided below the first sacrificial hard mask, forming a first spacer over the first sacrificial hard mask layer, forming a first sacrificial hard mask pattern by etching the first sacrificial hard mask layer using the first spacer as an etch mask, forming a second spacer at sidewalls of the first sacrificial hard mask pattern, partially isolating the second spacer, forming a pad mask pattern over the second spacer, and forming a pad pattern by etching the etch layer using the pad mask pattern.

The method may further include, after forming the first sacrificial hard mask layer, forming a sub hard mask layer over the first sacrificial hard mask layer.

The sub hard mask layer may include polysilicon.

The forming of the first sacrificial hard mask pattern may include forming a sub hard mask pattern by etching the sub hard mask layer using the first spacer as an etch mask, removing the first spacer, and etching the first sacrificial hard mask layer using the sub hard mask pattern as an etch mask.

The removing of the first spacer may be performed by wet-etching.

The removing of the first spacer may use a hydrofluoric acid (HF)-based etching solution or a H₃PO₄-based etching solution.

The forming of the first spacer may include forming a second sacrificial hard mask pattern over the first sacrificial hard mask layer, forming a first spacer material over the second sacrificial hard mask pattern, performing a first etch-back process on the first spacer material, and removing the second sacrificial hard mask pattern.

The forming of the first spacer material may be performed at a temperature substantially 20° C.˜substantially 400° C.

The forming of the second spacer may include forming a second spacer material over the first sacrificial hard mask pattern, performing a secondary etch-back process on the second spacer material, and removing the first sacrificial hard mask pattern.

The forming of the second spacer material may be performed at a temperature substantially 20° C.˜substantially 400° C.

The partially isolating of the second spacer may include forming a cutting mask to expose some parts of the second spacer, and etching the second spacer using the cutting mask as an etch mask.

The method may further include forming a target hard mask layer over the underlying layer.

The target hard mask layer may include a polysilicon layer.

In accordance with another aspect of the present invention, a method for forming a semiconductor device includes forming an underlying layer over a semiconductor substrate, forming a first spacer pattern defining a drain select line (DSL) over the underlying layer, the DSL extending from a cell region to a peripheral region in the semiconductor substrate defining a pad contact region coupled to the first spacer pattern in the peripheral region, forming a mask pattern at a sidewall of the first spacer pattern in the pad contact region to obtain a pad mask pattern, patterning the underlying layer using the first spacer pattern and the pad mask pattern as an etch mask to form a DSL extending from the cell region to the peripheral region and a pad contact pattern coupled to the DSL in the peripheral region.

The pad mask pattern may be wider than the first spacer pattern.

Distance between neighboring first spacer patterns in the pad contact region may be larger than the distance between neighboring first spacer patterns in the cell region.

Distance between neighboring first spacer patterns in the pad contact region may be larger than the distance between neighboring first spacer patterns in a non-pad contact region of the peripheral region.

The first spacer pattern may be formed using any of a Double Expose Etch Technology (DE2T), a Spacer Patterning Technology (SPT) and a Double Patterning Technology (DPT).

The peripheral region may include a plurality of pad contact regions, the plurality of pad contact regions are zigzagged in arrangement.

### BRIEF DESCRIPTION OF THE DRAWINGS

FIGS. 1A to 1N illustrate a method for forming a semiconductor device according to the present invention. In each of FIGS. 1A to 1N, (i) is a plan view illustrating a method for forming a semiconductor device according to an embodiment of the present invention, and (ii) is a cross-sectional view taken along the line x-x′ of the semiconductor device shown in (i).

### DESCRIPTION OF EMBODIMENTS

Reference will now be made in detail to the embodiments of the present invention, examples of which are illustrated in the accompanying drawings. Wherever possible, the same reference numbers will be used throughout the drawings to refer to the same or like parts.

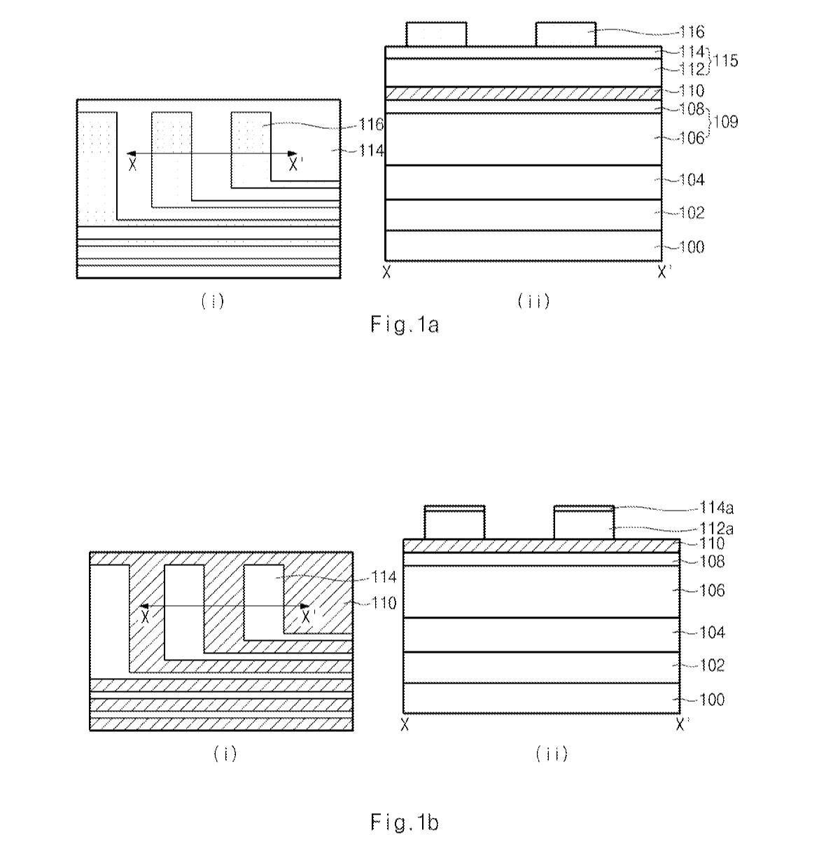

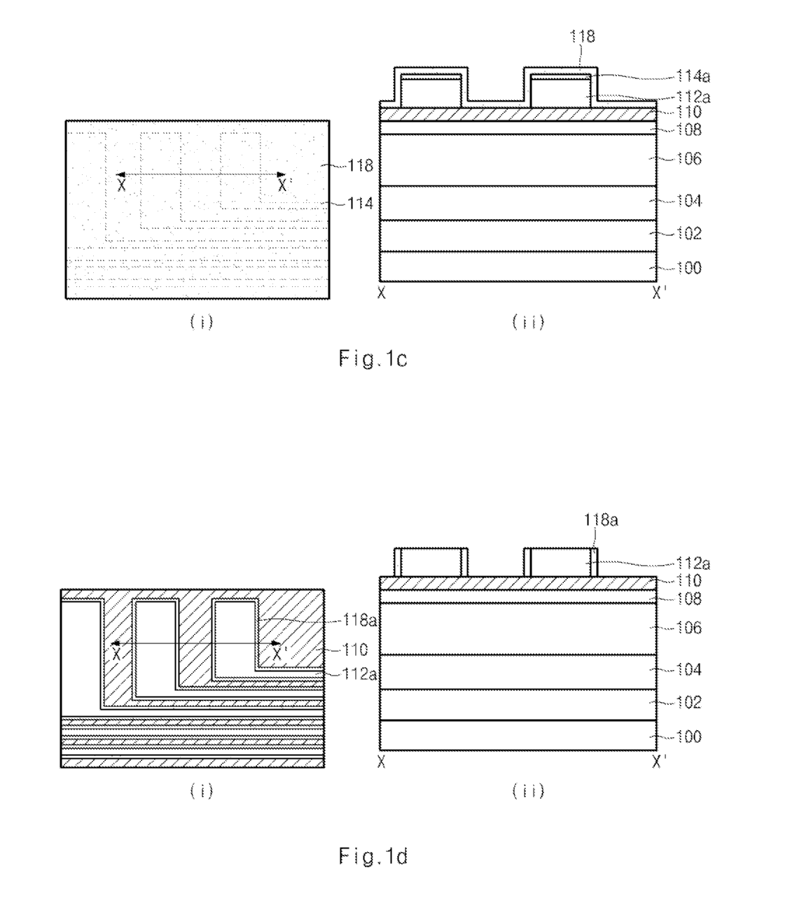

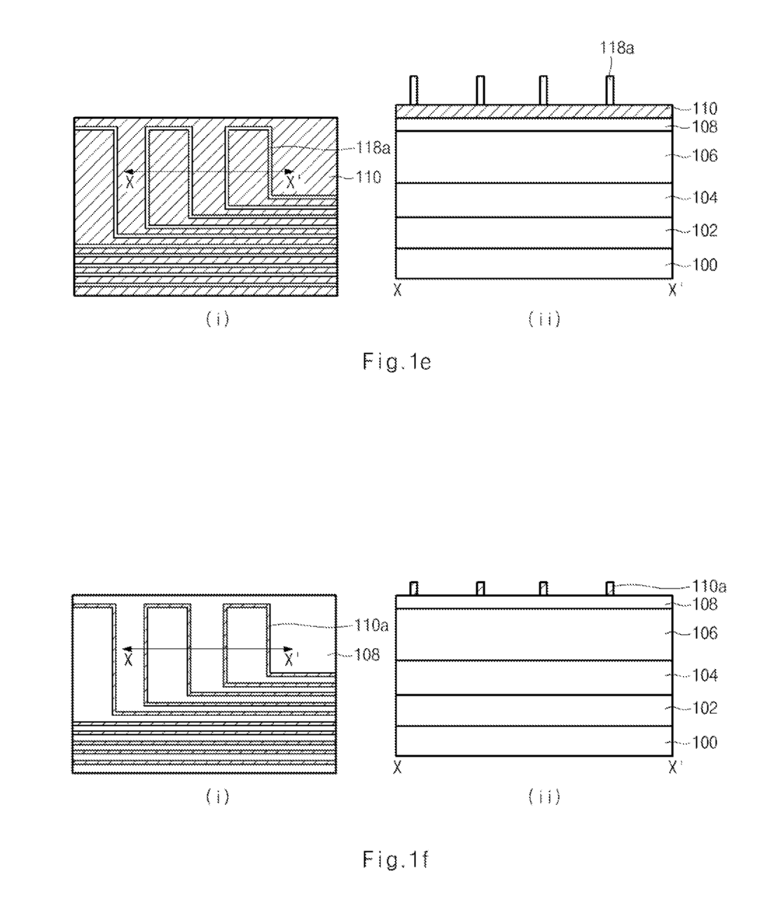

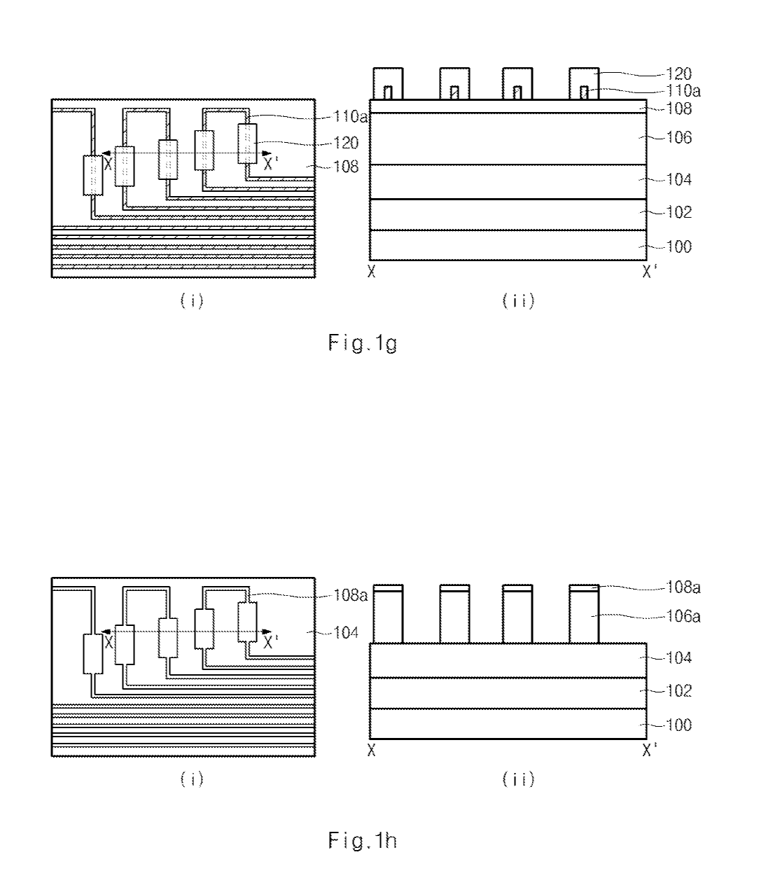

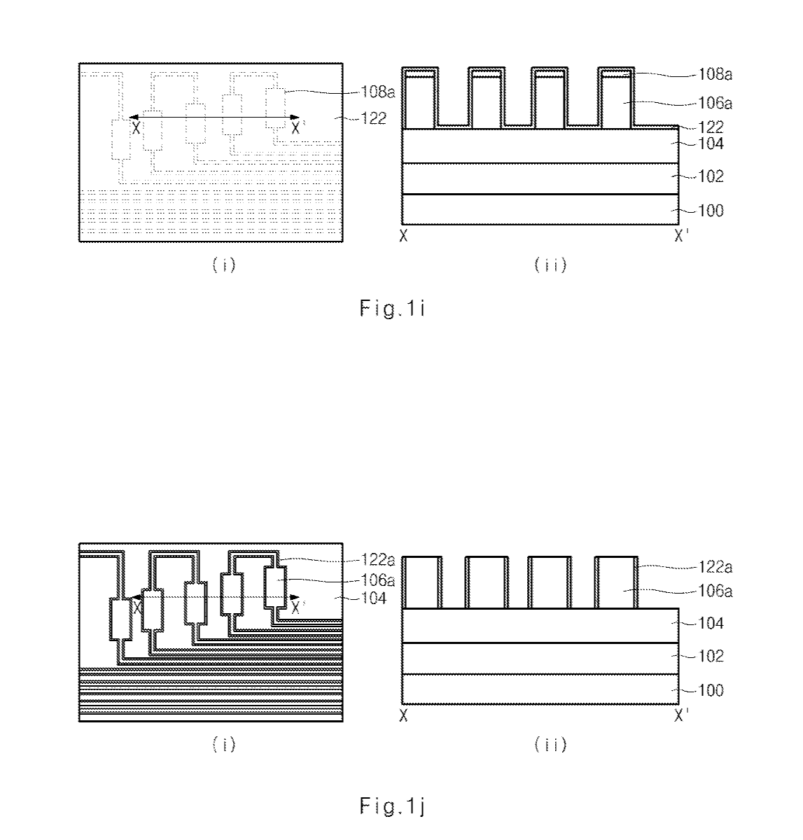

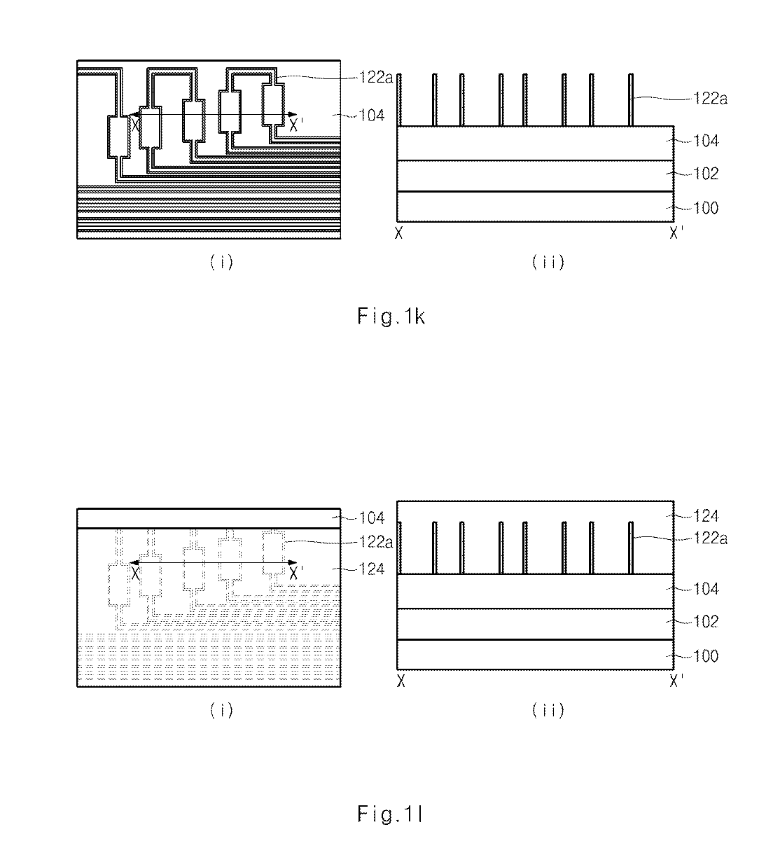

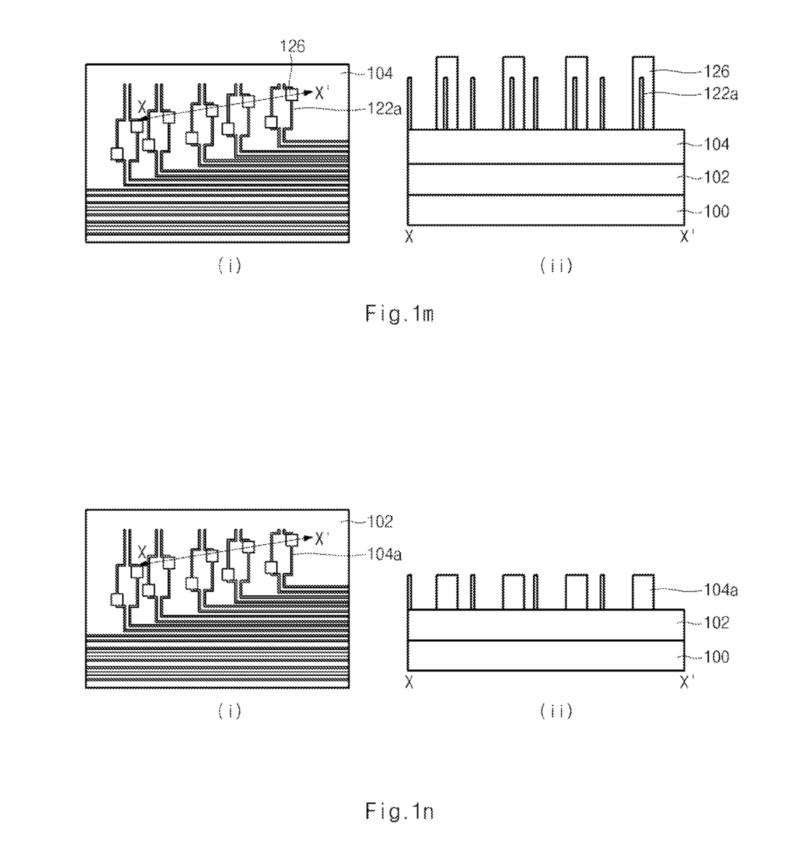

FIGS. 1A to 1N illustrate a method for forming a semiconductor device according to the present invention. In each of

FIGS. 1A to 1N, (i) is a plan view illustrating a method for forming a semiconductor device according to an embodiment of the present invention, and (ii) is a cross-sectional view taken along the line x-x′ of the semiconductor devices shown in (i) according to an embodiment of the present invention.

Prior to describing the method for forming the semiconductor device according to the present invention, a method for forming a pad region coupled to a drain contact for an X-decoder in a peripheral circuit region according to one embodiment of the present invention will be described in detail. The scope or spirit of the present invention is not limited to the method for forming a pad region coupled to the drain contact for the X-decoder. A method for forming a semiconductor device according to the present invention may also be applied to any patterning method for forming a microscopic device, especially for a device at a 10 nm level or so.

Referring to FIG. 1A, an underlying layer 102 to be etched, a target hard mask layer 104, a first sacrificial hard mask layer 109, a sub hard mask layer 110, and a second sacrificial hard mask layer 115 are sequentially deposited over the semiconductor substrate 100, and a first sacrificial photo resist pattern 116 is finally formed. Preferably, the first sacrificial hard mask layer 109 may be a stacked structure of a first sacrificial film 106 and a silicon oxide nitride film 108. Preferably, the second sacrificial hard mask layer 115 may be a stacked structure of a second sacrificial film 112 and a silicon oxide nitride film 114. In this case, a NAND flash control gate, that includes an Oxide/Nitride/Oxide (ONO) dielectric film, a gate poly, tungsten, and a capping silicon nitride film, may be additionally disposed under the underlying layer 102. However, the scope or spirit of the present invention is not limited thereto and can be modified by those skilled in the art in various ways.

Preferably, the underlying layer 102 to be etched may be an oxide layer, and a target hard mask layer 104 and a sub hard mask layer 110 may be formed of polysilicon. If the target hard mask layer 104 is formed of polysilicon, production cost of polysilicon is lower than amorphous carbon, and a wiggling phenomenon in which a high-aspect-ratio pattern is wiggled while being etched is prevented from being generated in fine pattern formation. However, although the target hard mask layer 104 is exemplarily formed of polysilicon for convenience of description, the target hard mask layer 104 may also be formed of other materials as necessary.

Preferably, the first sacrificial film 106 and the second sacrificial film 112 may be formed of amorphous carbon or spin on carbon (SOC) material. Both forms of carbon are easily removed by O₂ ashing, so that only spacers formed at sidewalls of the first and second sacrificial films 106 and 112 remain.

In addition, a pitch of the first photoresist pattern 116 may be changed according to a pitch of a target pattern, i.e., a pad pattern 104a shown in FIG. 1n. For example, if the target pattern has a pitch of X, it is preferable that a pitch of the first photoresist pattern 116 be set to 4X. In this case, the silicon oxide nitride film 108 and the silicon oxide nitride film 114 are not limited only to the above-mentioned materials, and may also be formed of various materials serving as a hard mask as necessary. Therefore, application of materials other than the silicon oxide nitride film 108 and the silicon oxide nitride film 114 may be readily used by those skilled in the art without departing from the scope and spirit of this invention.

Referring to FIG. 1B, a second sacrificial hard mask layer 115 is etched using the first photoresist pattern 116 as an etch mask, so that a stacked structure of the second sacrificial film pattern 112a and the silicon nitride film pattern 114a is formed. In this case, the second sacrificial film pattern 112a decides the height of a spacer, so that it is preferable that the second sacrificial film pattern 112a has a predetermined height defining the spacer.

Referring to FIG. 1C, a first spacer material 118 is formed over the entire surface. Preferably, the first spacer material 118 may be formed of a material that can be formed at a temperature (e.g., 20° C.˜400° C.) lower than that of the second sacrificial film 112, so that the first spacer material 118 cannot experience lifting due to thermal stress and can prevent a profile of the second sacrificial film pattern 112a from being distorted. For example, it is preferable that the first spacer material 118 be formed of a low-temperature oxide film or low-temperature nitride film having good step coverage.

Referring to FIGS. 1D and 1E, a first etch-back process is performed on the first spacer material 118, the first spacer material 118 is etched to expose the top surface of the second sacrificial film pattern 112a, so that a first spacer 118a is formed (See FIG. 1D). During the etching process, a silicon nitride film pattern 114a, which was formed over the second sacrificial film pattern 112a, is also removed. Subsequently, it is preferable that the second sacrificial film pattern 112a be removed by O₂ ashing (See FIG. 1E). In this case, the first spacer 118a may be formed in a horn shape.

Referring to FIG. 1F, the sub hard mask layer 110 is etched using the first spacer 118a as an etch mask, so that a sub hard mask pattern 110a is formed. When a structure underlying the sub hard mask layer 110 is etched using the horn-shaped first spacer 118a as an etch mask, the formation of the sub hard mask pattern 110a may prevent the underlying structure from being asymmetrically etched. That is, after the sub hard mask pattern 110a is configured in a horizontal symmetric form by first etching the sub hard mask layer 110 using the first spacer 118a as an etch mask, the lower structure can be etched in a symmetrical form using the sub hard mask pattern 110a as an etch mask. As a result, a spacer pattern to be formed in a subsequent process can be easily formed.

Next, the first spacer 118a is removed, preferably by wet-etching. If the first spacer material is a low-temperature oxide layer, it is preferable that the first spacer be etched using hydrofluoric acid (HF)-based etching solution. If the spacer material is a low-temperature nitride layer, it is preferable that the spacer be etched using H₃PO₄-based etching solution.

Referring to FIG. 1G, a second photoresist pattern 120 is formed over the sub hard mask pattern 110a. In a subsequent process, a pad pattern is formed at both ends of the second photoresist pattern 120, so it is preferable that the second photoresist pattern 120 be formed to have enough width for separation of the pad pattern.

Referring to FIG. 1H, the first sacrificial hard mask layer 109 is etched using the sub hard mask pattern 110a and the second photoresist pattern 120 as an etch mask, so that the first sacrificial hard mask pattern including the silicon oxide nitride film pattern 108a and the first sacrificial film pattern 106a is formed.

Referring to FIG. 1I, a second spacer material 122 is formed over the entire surface. Preferably, the second spacer material 122 may be formed of a material that can be formed at a temperature lower than that of the first sacrificial film 106, e.g., 20° C.˜400° C., so that the second spacer material 122 is not lifted due to thermal stress and a profile of the first sacrificial film pattern 106a is not distorted. For example, it is preferable that the second spacer material 122 be formed of a low-temperature oxide film or low-temperature nitride film having good step coverage.

Referring to FIGS. 1J and 1K, an etch-back process is performed on the second spacer material 122, wherein the second spacer material 122 is etched to expose the top surface of the first sacrificial film pattern 106a, so that a second spacer 122a is formed (See FIG. 1J). During the etching process, a silicon oxide nitride film pattern 108a formed over the first sacrificial film pattern 106a is also removed. Subsequently, it is preferable that the first sacrificial film pattern 106a be removed by O₂ ashing (See FIG. 1K).

Referring to FIG. 1L, a third photoresist pattern 124 is selectively formed to expose an edge of the upper surface, and an end of the second spacer 122a is removed using the third photoresist pattern 124 as an etch mask. In this case, the third photoresist pattern 124 is used as a cutting mask. In order to isolate the second spacers 122a, it is preferable that an end of the second spacer 122a is exposed. Subsequently, the third photoresist pattern 124 is removed.

Referring to FIG. 1M, a photoresist film is deposited over the second spacer 122a, and a fourth photoresist pattern 126 is formed using an etch mask. Preferably, the fourth photoresist pattern 126 may define a pad pattern.

Referring to FIG. 1N, the hard mask layer 104 is etched using the fourth photoresist pattern 126 and the second spacer 122a as an etch mask, thus forming a hard mask pattern 104a.

Although not shown in the drawings, the underlying layer 102 is etched using the target hard mask pattern 104a as a mask, so that a select transistor located at both ends of a string, a Source Select Line (SSL), and a Drain Select Line (DSL) are defined in a cell region, and a pad pattern coupled to a drain contact is defined in a peripheral circuit region.

As is apparent from the above description, a method for forming a semiconductor device according to the embodiment of the present invention can use a double spacer patterning (DPT) technology differently from the related art, so that a select transistor located at both ends of the string, a Source Select Line (SSL) and a Drain Select Line (DSL) can be readily formed in a cell region, and a pad pattern coupled to a drain contact can be readily formed in a peripheral circuit region.

The above embodiments of the present invention are illustrative and not limitative. Various alternatives and equivalents are possible. The invention is not limited by the type of deposition, etching polishing, and patterning steps described herein. Nor is the invention limited to any specific type of semiconductor device. For example, the present invention may be implemented in a dynamic random access memory (DRAM) device or a non-volatile memory device. Other additions, subtractions, or modifications are obvious in view of the present disclosure and are intended to fall within the scope of the appended claims.

What is claimed is:

1. A method for forming a semiconductor device comprising:
forming a first sacrificial hard mask layer over a semiconductor substrate including an underlying layer, the underlying layer being provided below the first sacrificial hard mask;
forming a first spacer over the first sacrificial hard mask layer;
forming a first sacrificial hard mask pattern by etching the first sacrificial hard mask layer by using the first spacer as an etch mask;
forming a second spacer over sidewalls of the first sacrificial hard mask pattern;
partially isolating the second spacer;
forming a pad mask pattern over the second spacer; and
forming a pad pattern by etching the underlying layer using the pad mask pattern.

2. The method according to claim 1, further comprising:
forming a sub hard mask layer over the first sacrificial hard mask layer.

3. The method according to claim 2, wherein the sub hard mask layer includes polysilicon.

4. The method according to claim 2, wherein the forming of the first sacrificial hard mask pattern includes:
forming a sub hard mask pattern by etching the sub hard mask layer using the first spacer as an etch mask;
removing the first spacer; and
etching the first sacrificial hard mask layer using the sub hard mask pattern as an etch mask.

5. The method according to claim 4, wherein the removing of the first spacer is performed by wet-etching.

6. The method according to claim 4, wherein the removing of the first spacer uses a hydrofluoric acid (HF)-based etching solution or a H₃PO₄-based etching solution.

7. The method according to claim 1, wherein the forming of the first spacer includes:
forming a second sacrificial hard mask pattern over the first sacrificial hard mask layer;
forming a first spacer material over the second sacrificial hard mask pattern;
performing a first etch-back process on the first spacer material; and
removing the second sacrificial hard mask pattern.

8. The method according to claim 7, wherein the forming of the first spacer material is performed at a temperature substantially 20° C.˜substantially 400° C.

9. The method according to claim 1, wherein the forming of the second spacer includes:
forming a second spacer material over the first sacrificial hard mask pattern;
performing a secondary etch-back process on the second spacer material; and
removing the first sacrificial hard mask pattern.

10. The method according to claim 9, wherein the forming of the second spacer material is performed at a temperature substantially 20° C.˜substantially 400° C.

11. The method according to claim 1, wherein the partially isolating of the second spacer includes:
forming a cutting mask to expose some parts of the second spacer; and
etching the second spacer by using the cutting mask as an etch mask.

12. The method according to claim 1, further comprising:
forming a target hard mask layer over the underlying layer.

13. The method according to claim 12, wherein the target hard mask layer includes polysilicon.

14. A method for forming a semiconductor device comprising:
forming an underlying layer over a semiconductor substrate;
forming a first spacer pattern defining a drain select line (DSL) over the underlying layer, the DSL extending from a cell region to a peripheral region in the semiconductor substrate;
defining a pad contact region coupled to the first spacer pattern in the peripheral region;
forming a mask pattern at a sidewall of the first spacer pattern in the pad contact region to obtain a pad mask pattern; and
patterning the underlying layer using the first spacer pattern and the pad mask pattern as an etch mask to form a DSL extending from the cell region to the peripheral region and a pad contact pattern coupled to the DSL in the peripheral region.

15. The method of claim 14, wherein the pad mask pattern is wider than the first spacer pattern.

16. The method of claim 14, wherein distance between neighboring first spacer patterns in the pad contact region is larger than the distance between neighboring first spacer patterns in the cell region.

17. The method of claim 14, wherein distance between neighboring first spacer patterns in the pad contact region is larger than the distance between neighboring first spacer patterns in a non-pad contact region of the peripheral region.

18. The method of claim 14, wherein the first spacer pattern is formed using any of a Double Expose Etch Technology (DE2T), a Spacer Patterning Technology (SPT) and a Double Patterning Technology (DPT).

19. The method of claim 14, wherein the peripheral region includes a plurality of pad contact regions,
wherein the plurality of pad contact regions are zigzagged in arrangement.
